(19) United States
(12) Patent Application Publication
(10) Pub. No.: US 2024/0292668 A1
(43) Pub. Date: Aug. 29, 2024

(54) DISPLAY PANEL AND DISPLAY APPARATUS INCLUDING THE SAME

(71) Applicant: Samsung Display Co., Ltd., Yongin-Si (KR)

(72) Inventors: Hosik Shin, Yongin-si (KR); Gyehwan Lim, Yongin-si (KR); Hyejin Joo, Yongin-si (KR)

(21) Appl. No.: 18/534,736

(22) Filed: Dec. 11, 2023

(30) Foreign Application Priority Data
Feb. 27, 2023 (KR) 10-2023-0026185

(51) Int. Cl. H10K 59/122; H10K 59/131; H10K 59/80

(52) U.S. Cl. CPC H10K 59/122; H10K 59/131; H10K 59/873; H10K 59/8792

(57) ABSTRACT

A display panel is provided. The display panel includes a substrate including a display area and a peripheral area around the display area, an organic insulating layer disposed on the substrate, a light-emitting element disposed on the substrate in the display area, a first bank layer including a light absorbing-material, disposed on the organic insulating layer, and including a first alignment opening in the peripheral area, and a common voltage line disposed between the substrate and the organic insulating layer in the peripheral area, and overlapping the first alignment opening in a plan view. The first alignment opening forms an alignment pattern.

### CROSS-REFERENCE TO RELATED APPLICATION

This application is based on and claims priority under 35 U.S.C. § 119 to Korean Patent Application No. 10-2023-0026185, filed on Feb. 27, 2023, in the Korean Intellectual Property Office, the disclosure of which is incorporated by reference herein in its entirety.

### BACKGROUND

### 1. Field

One or more embodiments relate to a display panel and a display apparatus including the same, and more particularly, to a display panel with an extended display area such that images may be also displayed on lateral surfaces and corner regions thereof, and a display apparatus including the display panel.

### 2. Description of the Related Art

Recently, the design of display apparatuses has diversified. As an example, curved display apparatuses, foldable display apparatuses, and rollable display apparatuses have been developed. In addition, a display area has been extended and a non-display area has been reduced. Accordingly, various methods have been used to design the shape of a display apparatus.

### SUMMARY

One or more embodiments include a display panel with an extended display area such that images may be also displayed in corner regions, and a display apparatus including the display panel.

However, such a technical problem is just an example, and the disclosure is not limited thereto.

Additional aspects will be set forth in part in the description which follows and, in part, will be apparent from the description, or may be learned by practice of the presented embodiments of the disclosure.

According to one or more embodiments, a display panel includes a substrate including a display area and a peripheral area around the display area, an organic insulating layer disposed on the substrate, a light-emitting element disposed on the substrate in the display area, a first bank layer including a light-absorbing material, disposed on the organic insulating layer, and including a first alignment opening in the peripheral area, and a common voltage line disposed between the substrate and the organic insulating layer in the peripheral area, and overlapping the first alignment opening in a plan view, wherein the first alignment opening forms an alignment pattern.

The first bank layer may include a first pixel opening in the display area, and the light-emitting element may be disposed in the first pixel opening.

The first bank layer may be in contact with the organic insulating layer in the peripheral area.

The display panel may further include a peripheral connection electrode disposed on the common voltage line to be in contact with the common voltage line, wherein the peripheral connection electrode may overlap the first alignment opening in a plan view.

The organic insulating layer may include a first organic insulating layer, and a second organic insulating layer disposed on the first organic insulating layer, wherein at least a portion of the peripheral connection electrode may be disposed between the first organic insulating layer and the second organic insulating layer.

The display panel may further include an inorganic protective layer disposed on the peripheral connection electrode to be in contact with the peripheral connection electrode, wherein the inorganic protective layer may overlap the first alignment opening.

The organic insulating layer may include a third organic insulating layer disposed on a second organic insulating layer, and a fourth organic insulating layer disposed on the third organic insulating layer, wherein the first bank layer may cover the fourth organic insulating layer in the peripheral area.

The display panel may further include an inorganic layer disposed between the second organic insulating layer and the third organic insulating layer in the peripheral area.

The first bank layer may be in contact with the inorganic layer.

The display panel may further include a second bank layer disposed on the organic insulating layer and including a second pixel opening in the display area, wherein the light-emitting element may be disposed in the second pixel opening, and the second bank layer may be disposed between the organic insulating layer and the first bank layer in the peripheral area.

According to one or more embodiments, a display apparatus includes a cover window including a plane portion and a curved portion bent in a corner of the plane portion, and a display panel disposed on one surface of the cover window, wherein the display panel includes a substrate including a display area and a peripheral area surrounding the display area, wherein the display area overlaps the plane portion, an organic insulating layer disposed on the substrate, a light-emitting element disposed on the substrate in the display area, a first bank layer including a light-absorbing material, disposed on the organic insulating layer, and including a first alignment opening in the peripheral area, and a common voltage line disposed between the substrate and the organic insulating layer in the peripheral area, and overlapping the first alignment opening in a plan view, wherein the first alignment opening forms an alignment pattern.

The first bank layer may include a first pixel opening in the display area, and the light-emitting element may be disposed in the first pixel opening.

The first bank layer may be in contact with the organic insulating layer in the peripheral area.

The display panel may further include a peripheral connection electrode disposed on the common voltage line to be in contact with the common voltage line, wherein the peripheral connection electrode may overlap the first alignment opening in a plan view.

The organic insulating layer may include a first organic insulating layer, and a second organic insulating layer disposed on the first organic insulating layer, wherein at least a portion of the peripheral connection electrode may be disposed between the first organic insulating layer and the second organic insulating layer.

The display panel may further include an inorganic protective layer disposed on the peripheral connection electrode to be in contact with the peripheral connection electrode, wherein the inorganic protective layer may overlap the first alignment opening.

The organic insulating layer may include a third organic insulating layer disposed on a second organic insulating layer, and a fourth organic insulating layer disposed on the third organic insulating layer, wherein the first bank layer may cover the fourth organic insulating layer in the peripheral area.

The display panel may further include an inorganic layer disposed between the second organic insulating layer and the third organic insulating layer in the peripheral area.

The first bank layer may be in contact with the inorganic layer.

The display panel may further include a second bank layer disposed on the organic insulating layer in the display area and including a second pixel opening, wherein the light-emitting element may be disposed in the second pixel opening, and the second bank layer may be disposed between the organic insulating layer and the first bank layer in the peripheral area.

These and/or other aspects will become apparent and more readily appreciated from the following detailed description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2 is a schematic exploded perspective view of a display panel and a cover window of a display apparatus according to an embodiment;

FIG. 3 is a schematic perspective view of a display panel according to an embodiment;

FIG. 4 is a schematic cross-sectional view of a display apparatus according to an embodiment;

FIG. 5 is a schematic plan view showing an unfolded state of a display panel that may be included in the display apparatus of FIG. 1 according to an embodiment;

FIG. 6 is an enlarged view of a region II of FIG. 5;

FIG. 7 is a schematic cross-sectional view of a portion of the display panel according to an embodiment;

FIG. 8 is an equivalent circuit diagram of a pixel circuit applicable to a display panel according to an embodiment;

FIGS. 9 and 10 are schematic cross-sectional views of a portion of a display panel according to an embodiment;

FIGS. 11 and 12 are schematic plan views of a portion of a display panel according to an embodiment; and

FIGS. 13 and 14 are schematic cross-sectional views of a portion of a display panel according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

In the case where a certain embodiment may be implemented differently, a specific process order may be performed in the order different from the described order. As an example, two processes successively described may be simultaneously performed substantially and performed in the opposite order.

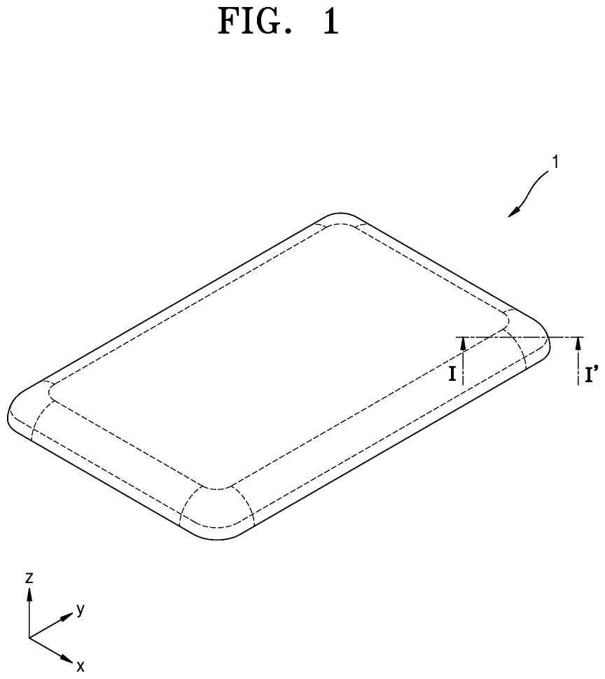

FIG. 1 is a schematic perspective view of a display apparatus 1 according to an embodiment.

Referring to FIG. 1, the display apparatus 1 is an apparatus for displaying moving images or still images and may include portable electronic apparatuses such as mobile phones, smartphones, tablet personal computers, mobile communication terminals, electronic organizers, electronic books, portable multimedia players (PMPs), navigations, and ultra mobile personal computers (UMPCs), and the like. In addition, the display apparatus 1 may be an electronic apparatus configured to provide a display screen such as televisions, notebook computers, monitors, advertisement boards, Internet of things (IoTs), and the like. Alternatively, the display apparatus 1 may be wearable devices including smartwatches, watchphones, glasses-type displays, or head-mounted displays (HMDs).

In an embodiment, the display apparatus 1 may have a quadrangular shape in a plan view. In an embodiment, the display apparatus 1 may have various shapes such as triangles, polygons such as quadrangles, circular shapes, elliptical shapes, and the like. In an embodiment, in the case where the display apparatus 1 has a polygonal shape in a plan view, a corner of the polygon may be round. Hereinafter, for convenience of description, the case where the display apparatus 1 has a quadrangular shape in which corners are round in a plan view is mainly described.

The display apparatus 1 may have short sides in a first direction (e.g., an x direction or a −x direction) and long sides in a second direction (e.g., a y direction or a −y direction). In another embodiment, the length of the sides in the first direction (e.g., the x direction or the −x direction) of the display apparatus 1 and the length of the sides in the second direction (e.g., the y direction or the −y direction) may be the same. In another embodiment, the display apparatus 1 may have long sides in the first direction (e.g., the x direction or the −x direction) and short sides in the second direction (e.g., the y direction or the −y direction). Each corner at which the short side in the first direction (e.g., the x direction or the −x direction) and the long side in the second direction (e.g., the y direction or the −y direction) meet each other may be round to have a preset curvature.

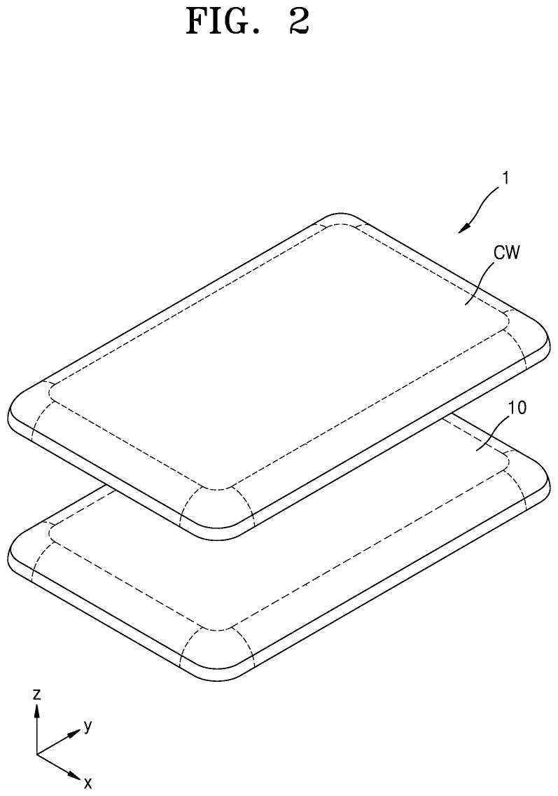

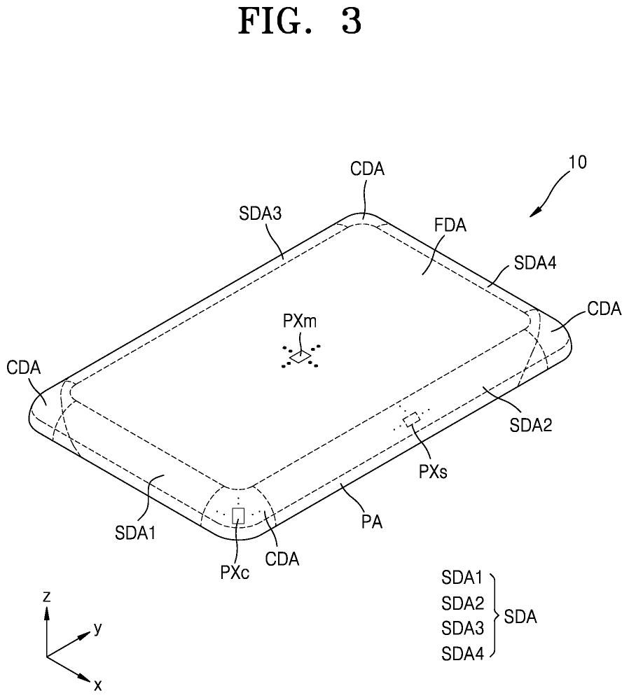

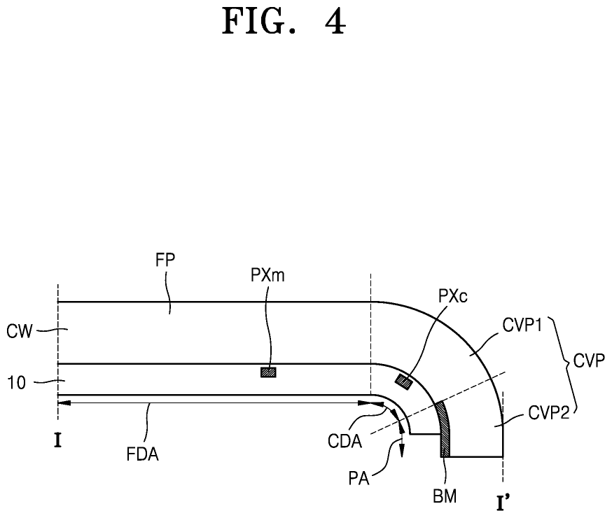

FIG. 2 is a schematic exploded perspective view of a display panel and a cover window of the display apparatus according to an embodiment. FIG. 3 is a schematic perspective view of a display panel according to an embodiment. FIG. 4 is a schematic cross-sectional view of the display apparatus according to an embodiment. FIG. 4 may correspond to a line I-I′ of FIG. 1.

Referring to FIGS. 2 to 4, the display apparatus 1 may include a display panel 10 and a cover window CW disposed on the display panel 10.

The display panel 10 may include a front display area FDA, a side display area SDA, and a corner display area CDA as a display area. The display apparatus 1 may include a peripheral area PA surrounding the display area.

The front display area FDA is a region disposed on the front portion of the display panel 10 and is a region formed flat without being bent. The front display area FDA may occupy the largest ratio in the display area of the display panel 10 and accordingly provide most of images. That is, the front display area FDA is a main display area. The front display area FDA may have a rectangular shape including short sides in the x direction, long sides in the y direction, and each round corner.

At least a portion of the side display area SDA is bent to include a curved surface and may extend to the outside from each side of the front display area FDA. The side display area SDA may include a first side display area SDA1, a second side display area SDA2, a third side display area SDA3, and a fourth side display area SDA4. In an embodiment, at least one of the first side display area SDA1, the second side display area SDA2, the third side display area SDA3, and the fourth side display area SDA4 may be omitted.

The first side display area SDA1 may be a region extending from a first side of the front display area FDA and bent at a preset curvature. The first side display area SDA1 may extend from the lower side of the front display area FDA. The first side display area SDA1 may be a region disposed on the lower side surface of the display panel 10.

The second side display area SDA2 may be a region extending from a second side of the front display area FDA and bent at a preset curvature. The second side display area SDA2 may extend from the right side of the front display area FDA. The second side display area SDA2 may be a region disposed on the right side surface of the display panel 10.

The third side display area SDA3 may be a region extending from a third side of the front display area FDA and bent at a preset curvature. The third side display area SDA3 may extend from the left side of the front display area FDA. The third side display area SDA3 may be a region disposed on the left side surface of the display panel 10.

The fourth side display area SDA4 may be a region extending from a fourth side of the front display area FDA and bent at a preset curvature. The fourth side display area SDA4 may extend from the upper side of the front display area FDA. The fourth side display area SDA4 may be a region disposed on the upper side surface of the display panel 10.

The first to fourth side display areas SDA1, SDA2, SDA3, and SDA4 may each include a curved surface bent at a preset curvature. As an example, the first side display area SDA1 and the fourth side display area SDA4 may each have a curved surface bent around a bending axis extending in the x direction, and the second side display area SDA2 and the third side display area SDA3 may each have a curved surface bent around a bending axis extending in the y direction. The curvatures of the first to fourth side display areas SDA1, SDA2, SDA3, and SDA4 may be the same or different from each other.

The corner display area CDA may be a region extending from the corner of the front display area FDA and bent at a preset curvature. The corner display area CDA may be arranged between the first to fourth side display areas SDA1, SDA2, SDA3, and SDA4. As an example, the corner display area CDA may be arranged between the first side display area SDA1 and the second side display area SDA2, between the first side display area SDA1 and the third side display area SDA3, between the second side display area SDA2 and the fourth side display area SDA4, and between the third side display area SDA3 and the fourth side display area SDA4.

Because the corner display area CDA is located between the adjacent side display areas SDA having curved surfaces bent in different directions, the corner display area CDA may include a curved surface in which curved surfaces bent in various directions are continuously connected to each other. In addition, in the case where the curvatures of the adjacent side display areas SDA are different from each other, the curvature of the corner display area CDA may gradually change along the edge of the display apparatus 1. As an example, in the case where the curvature of the first side display area SDA1 is different from the curvature of the second side display area SDA2, the corner display area CDA between the first side display area SDA1 and the second side display area SDA2 may have a curvature gradually changing depending on a position thereof.

The display panel 10 may be configured to display images using main pixels PXm arranged in the front display area FDA, side pixels PXs arranged in the side display area SDA, and corner pixels PXc arranged in the corner display area CDA. Because the display panel 10 is configured to display images on the side display area SDA and the corner display area CDA in addition to the front display area FDA, the proportion of the display area in the display apparatus 1 may increase. That is, in the display apparatus 1 having the same size, the area of the peripheral area PA may be reduced, and the area of the display area may be increased.

The peripheral area PA may be arranged to entirely or partially surround the outside of the side display area SDA and the corner display area CDA. The peripheral area PA is a region in which images are not displayed. Various wirings and driving circuits may be arranged in the peripheral area PA. A shield such as a light-blocking member may be provided in the peripheral area PA such that members disposed in the peripheral area PA are not visually recognized.

Referring to FIG. 4, the cover window CW may be disposed on the front surface of the display panel 10. Here, the front surface of the display panel 10 may be defined as a surface facing a direction in which the display panel 10 is configured to display images. That is, the display panel 10 may be disposed on one surface of the cover window CW.

The cover window CW may cover and protect the display panel 10. The cover window CW may have a high transmittance to transmit light emitted from the display panel 10, and have a thin thickness to reduce the weight of the display apparatus 1. In addition, the cover window CW may have high strength and hardness to protect the display panel 10 from external impacts.

The cover window CW may include a transparent material. The cover window CW may include, for example, glass or plastic. In the case where the cover window CW includes plastic, the cover window CW may be flexible. As an example, the cover window CW may be an ultra-thin glass (UTG®) whose strength is strengthened by a method such as chemical strengthening or thermal strengthening. In another embodiment, the cover window CW may be, for example, ultra-thin glass (UTG®) or colorless polyimide (CPI). In an embodiment, the cover window CW may have a structure in which a flexible polymer layer is disposed on one surface of a glass substrate, or include only a polymer layer.

The cover window CW may include a flat portion FP and a curved portion CVP, wherein the flat portion FP may be disposed in an area corresponds to the front display area FDA of the display panel 10, and the curved portion CVP may be disposed in an area corresponds to the corner display area CDA.

The flat portion FP of the cover window CW may be provided as a plane and may overlap the front display area FDA of the display panel 10. The curved portion CVP of the cover window CW may include a curved surface. In this case, the curved portion CVP may have a preset curvature or a varying curvature. The curved portion CVP may include a first curved portion CVP1 and a second curved portion CVP2. The first curved portion CVP1 may be arranged to overlap the side display area SDA and the corner display area CDA of the display panel 10. The second curved portion CVP2 may be arranged to overlap the peripheral area PA of the display panel 10. The first curved portion CVP1 may be arranged between the flat portion FP and the second curved portion CVP2.

A light-blocking member BM may be disposed in a portion of the second curved portion CVP2 of the cover window CW. The light-blocking member BM is intended to hide a lower structure disposed thereunder and may overlap the peripheral area PA of the display panel 10. The light-blocking member BM may include a light-blocking material. The light-blocking member BM may include carbon black, carbon nano tubes, and resin including black dye. Alternatively, the light-blocking member BM may include nickel, aluminum, molybdenum, and an alloy thereof. The light-blocking member BM may be coated using an inkjet method or attached in a film type.

The display panel 10 may be disposed under the cover window CW. The cover window CW and the display panel 10 may be coupled to each other by an adhesive member (not shown). The adhesive member may be an optically cleared adhesive film (OCA) or an optically cleared resin (OCR).

The display panel 10 may be configured to display images using the main pixels PXm arranged in the front display area FDA and the corner pixels PXc arranged in the corner display area CDA. A lower protective film (not shown) may be further disposed under the display panel 10 to protect the display panel 10.

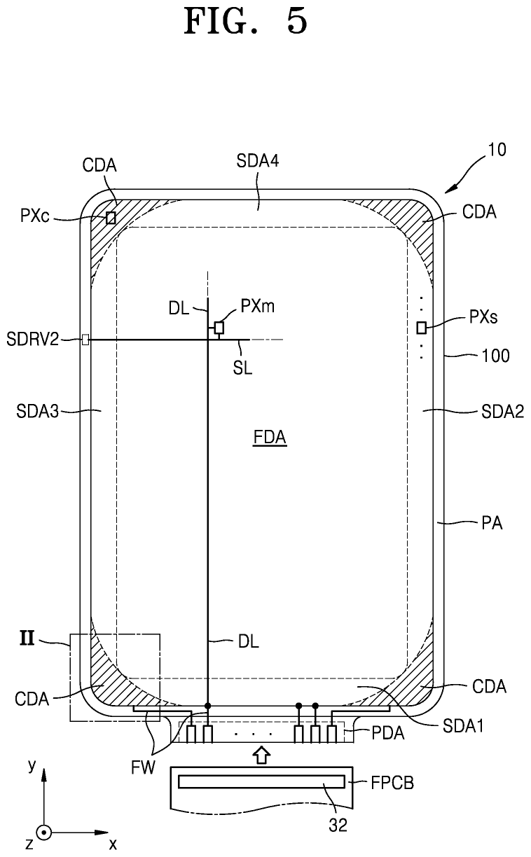

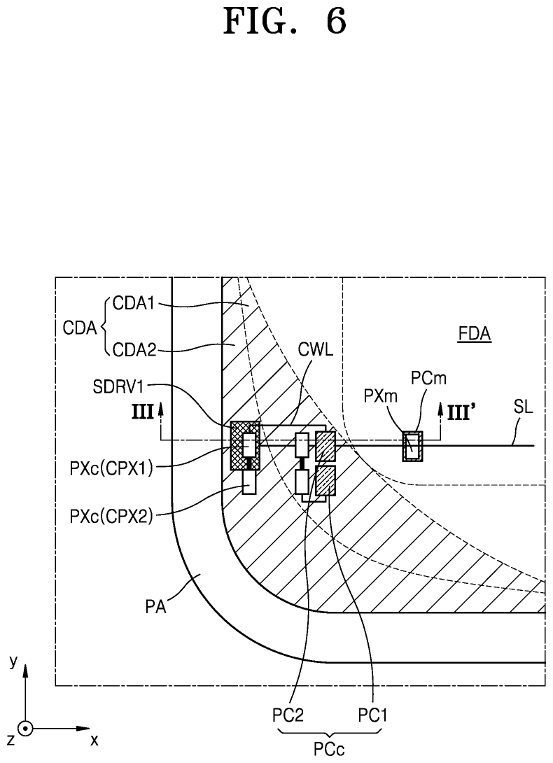

FIG. 5 is a schematic plan view showing an unfolded state of the display panel 10 that may be included in the display apparatus of FIG. 1 according to an embodiment. FIG. 6 is an enlarged view of a region II of FIG. 5.

Referring to FIGS. 5 and 6, various kinds of elements constituting the display panel 10 are disposed on the substrate 100. The substrate 100 includes the front display area FDA, the side display area SDA, the corner display area CDA, and the peripheral area PA.

The plurality of main pixels PXm may be arranged in the front display area FDA, and main images may be displayed using the main pixels PXm. The main pixel PXm may include a plurality of sub-pixels. Each sub-pixel may be configured to emit red, green, blue, or white light.

The side display area SDA may be disposed above, below, left, or right of the front display area FDA. The plurality of side pixels PXs may be arranged in the side display area SDA, and side images may be displayed using the side pixels PXs. A side image may form one entire image in cooperation with a main image. Alternatively, a side image may be an image independent of the main image.

The corner display area CDA may be arranged in a region extending from the front display area FDA. The corner display area CDA may be arranged between two side display areas SDA. The plurality of corner pixels PXc may be arranged in the corner display area CDA, and corner images may be displayed using the corner pixels PXc. A corner image may form one entire image in cooperation with a main image and a side image. Alternatively, a corner image may be an image independent of the main image.

Each of the corner display area CDA may include a first corner display area CDA1 and a second corner display area CDA2. The second corner display area CDA2 is a region extending from the first corner display area CDA1. The second corner display area CDA2 may be closer to the edge of the substrate 100 than the first corner display area CDA1. The first corner display area CDA1 may be arranged between the second corner display area CDA2 and the front display area FDA.

A driving circuit SDRV1 and the corner pixel PXc may be arranged in the second corner display area CDA2. The driving circuit SDRV1 may be configured to provide scan signals for the main pixels PXm and the corner pixels PXc respectively arranged in the front display area FDA and the corner display area CDA. In an embodiment, the driving circuit SDRV1 may be simultaneously connected to a pixel circuit configured to drive the corner pixels PXc and a pixel circuit configured to drive the main pixel PXm to provide the same scan signals. In this case, a scan line SL connected to the driving circuit SDRV1 may extend from the second corner display area CDA2 to the front display area FDA. The scan line SL may extend in the x direction.

The corner pixel PXc may overlap the driving circuit SDRV1 in the second corner display area CDA2. The pixel circuit PC2 configured to drive the corner pixel PXc arranged in the second corner display area CDA2 may be arranged in the first corner display area CDA1. Accordingly, pixel circuits PC1 and PC2 may be arranged in the first corner display area CDA1. The pixel circuits PC1 and PC2 may be configured to respectively drive the corner pixel PXc arranged in the first corner display area CDA1 and the corner pixel PXc arranged in the second corner display area CDA2. The corner pixel PXc arranged in the second corner display area CDA2 may be driven by the pixel circuit PC2 arranged in the first corner display area CDA1 and connected to the corner pixel PXc by a connection wiring CWL. The connection wiring CWL may extend in the x direction, which is a direction in which the scan line SL extends.

The corner pixel PXc arranged in the second corner display area CDA2 may include a first copy pixel CPX1 and a second copy pixel CPX2. The first copy pixel CPX1 and the second copy pixel CPX2 are driven by one pixel circuit and may be pixels configured to emit light of the same color. The first copy pixel CPX1 and the second copy pixel CPX2 may be substantially the same in size. Because the corner pixels PXc are provided as copy pixels, the number of pixel circuits configured to drive the corner pixels PXc may be reduced. Because the corner pixels PXc are arranged to overlap the driving circuit SDRV1, the corner display area CDA may be extended.

The peripheral area PA may be arranged outside the side display area SDA and the corner display area CDA. Various wirings, a driving circuit SDRV2, and a terminal portion PDA may be arranged in the peripheral area PA.

The driving circuit SDRV2 may be configured to provide scan signals for driving the main pixels PXm and the side pixels PXs. The driving circuit SDRV2 may be arranged on the right of the second side display area SDA2 and/or on the left of the third side display area SDA3 and connected to the scan line SL extending in the x direction.

The terminal portion PDA may be arranged below the first side display area SDA1. The terminal portion PDA may be exposed and a display circuit board FPCB may be connected to the exposed terminal portion PDA which is not covered by an insulating layer. A display driver 32 may be disposed on the display circuit board FPCB.

The display driver 32 may be configured to generate control signals transferred to the driving circuit SDRV1 and the driving circuit SDRV2. In addition, the display driver 32 may be configured to generate data signals. The generated data signals may be transferred to the pixels PXm, PXs, and PXc through a fan-out wiring FW and the data line DL connected to the fan-out wiring FW.

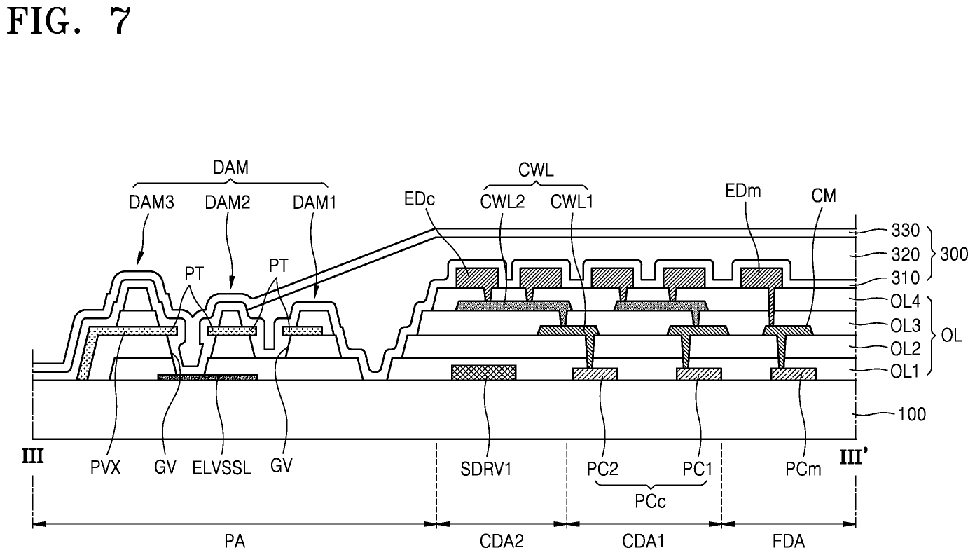

FIG. 7 is a schematic cross-sectional view of a portion of the display panel 10 according to an embodiment taken along line III-III′ of FIG. 6.

Referring to FIG. 7, the display panel 10 may include the front display area FDA, the corner display area CDA, and the peripheral area PA. The corner display area CDA may include the first corner display area CDA1 and the second corner display area CDA2.

The substrate 100 may include an insulating material such as glass, quartz, a polymer resin or the like. The substrate 100 may be a rigid substrate or a flexible substrate that is bendable, foldable, and rollable.

Pixel circuits PCm and PCc, the driving circuit SDRV1, light-emitting elements EDm and EDc, a thin-film encapsulation layer 300, and a dam portion DAM may be disposed on the substrate 100, wherein the pixel circuits PCm and PCc include thin-film transistors, the driving circuit SDRV1 is configured to provide scan signals to the pixel circuit, the light-emitting elements EDm and EDc are connected to the pixel circuits PCm and PCc and implement the pixels, and the thin-film encapsulation layer 300 covers and protects the light-emitting elements EDm and EDc. The pixel circuits PCm and PCc may include a main pixel circuit PCm and a corner pixel circuit PCc. The corner pixel circuit PCc may include a first corner pixel circuit PC1 and a second corner pixel circuit PC2. In an embodiment, all of the main pixel circuit PCm, the first corner pixel circuit PC1, and the second corner pixel circuit PC2 may include the same pixel circuit. In another embodiment, at least one of the main pixel circuits PCm, the first corner pixel circuit PC1, and the second corner pixel circuit PC2 may be modified or include a different pixel circuit.

An organic insulating layer OL may be disposed between the pixel circuits PCm and PCc and the light-emitting elements EDm and EDc. The organic insulating layer OL may include a plurality of organic insulating layers that are stacked. In an embodiment, the organic insulating layer OL may include a first organic insulating layer OL1, a second organic insulating layer OL2, a third organic insulating layer OL3, and a fourth organic insulating layer OL4 that are sequentially stacked.

The main pixel circuit PCm and a main light-emitting element EDm connected thereto may be arranged in the front display area FDA of the display panel 10. An emission area of the main light-emitting element EDm may correspond to the main pixel PXm (see FIG. 6). The main pixel circuit PCm may include at least one thin-film transistor and be configured to control light emission of the main light-emitting element EDm. The main light-emitting element EDm may be connected to the main pixel circuit PCm through a connection electrode CM. The main light-emitting element EDm may overlap at least a portion of the main pixel circuit PCm.

The first corner pixel circuit PC1 and the corner light-emitting element EDc connected thereto may be arranged in the first corner display area CDA1 of the display panel 10. An emission area of the corner light-emitting element EDc may correspond to the corner pixel PXc (see FIG. 6). The first corner pixel circuit PC1 may include at least one thin-film transistor and be configured to control light emission of at least two corner light-emitting elements EDc. In an embodiment, two corner light-emitting elements EDc may be connected to one first corner pixel circuit PC1 to simultaneously emit light. In this case, the two corner light-emitting elements EDc may be the copy pixels.

The second corner pixel circuit PC2 may be arranged in the first corner display area CDA1, wherein the second corner pixel circuit PC2 is connected to the corner light-emitting element EDc arranged in the second corner display area CDA2. The second corner pixel circuit PC2 may include at least one thin-film transistor and be configured to control light emission of at least two corner light-emitting elements EDc in the second corner display area CDA2. In an embodiment, two corner light-emitting elements EDc may be connected to one second corner pixel circuit PC2 to simultaneously emit light. In this case, the two corner light-emitting elements EDc may be the copy pixels.

The second corner pixel circuit PC2 disposed in the first corner display area CDA1 may be connected to the corner light-emitting element EDc disposed in the second corner display area CDA2 through the connection wiring CWL. The connection wiring CWL may include a first connection wiring CWL1 and a second connection wiring CWL2 disposed on different layers. The second corner pixel circuit PC2 may be connected to the corner light-emitting element EDc by only the first connection wiring CWL1, the second corner pixel circuit PC2 may be connected to the corner light-emitting element EDc by only the second connection wiring CWL2, or the second corner pixel circuit PC2 may be connected to the corner light-emitting element EDc by the first connection wiring CWL1 and the second connection wiring CWL2. However, various modifications may be made.

The driving circuit SDRV1 may be arranged in the second corner display area CDA2 of the display panel 10. The driving circuit SDRV1 may include at least one thin-film transistor and be configured to provide scan signals to the pixel circuits PCc and PCm arranged in the corner display area CDA and the front display area FDA, respectively. An emission control driving circuit (not shown) may be further arranged in the second corner display area CDA2, wherein the emission control driving circuit is configured to provide emission control signals which are different from the scan signals. The driving circuit SDRV1 and the emission control driving circuit may overlap the corner light-emitting element EDc.

The emission areas of the corner light-emitting elements EDc arranged in the first corner display area CDA1 and the second corner display area CDA2 may represent the corner pixels, and the corner pixels PXc may be arranged in the same pixel configuration in the first corner display area CDA1 and the second corner display area CDA2.

The main light-emitting element EDm and the corner light-emitting element EDc may be covered by the thin-film encapsulation layer 300. In an embodiment, the thin-film encapsulation layer 300 may include at least one inorganic encapsulation layer and at least one organic encapsulation layer. In an embodiment, the thin-film encapsulation layer 300 may include a first inorganic encapsulation layer 310, a second inorganic encapsulation layer 330, and an organic encapsulation layer 320 disposed therebetween.

A common voltage line ELVSSL and the dam portion DAM may be arranged in the peripheral area PA of the display panel 10, wherein the common voltage line ELVSSL is configured to transfer a common voltage to the light-emitting element. The dam portion DAM may overlap the common voltage line ELVSSL. The dam portion DAM may be designed to prevent an overflow of the organic encapsulation layer 320 of the thin-film encapsulation layer 300 and prevent external moisture transmission.

The dam portion DAM may include a plurality of dams. The dam portion DAM may include a first dam DAM1, a second dam DAM2, and a third dam DAM3. A groove GV may be formed between the plurality of dams, wherein the groove GV is a concave portion in a depth direction. The plurality of dams may include a plurality of organic insulating layers OL that are stacked. The first dam DAM1 and the second dam DAM2 may each include the first organic insulating layer OL1, the second organic insulating layer OL2, and the third organic insulating layer OL3 that are stacked.

In an embodiment, the first dam DAM1 and the second dam DAM2 may each further include an inorganic layer PVX between the second organic insulating layer OL2 and the third organic insulating layer OL3. The inorganic layer PVX may include a protrusion tip PT protruding in a direction of the center of the groove GV arranged between the first dam DAM1 and the second dam DAM2. Because an organic layer or an opposite electrode included in the light-emitting element is disconnected by the protrusion tip PT, a tolerance margin required when depositing the organic layer or the opposite electrode may be reduced. Accordingly, the area of the peripheral area PA may be remarkably reduced.

In an embodiment, the third dam DAM3 may include the first organic insulating layer OL1, the second organic insulating layer OL2, the third organic insulating layer OL3, and the fourth organic insulating layer OL4 that are stacked. The third dam DAM3 may further include the inorganic layer PVX disposed between the second organic insulating layer OL2 and the third organic insulating layer OL3. The inorganic layer PVX may cover the lateral surface of the third dam DAM3 disposed adjacent to the edge of the substrate 100. That is, the inorganic layer PVX may cover one lateral surface of the second organic insulating layer OL2, which is a second layer of the third dam DAM3. The inorganic layer PVX may extend from one side of the second organic insulating layer OL2 and be disposed on the upper surface of the substrate 100. Accordingly, the first inorganic encapsulation layer 310 of the thin-film encapsulation layer 300 may be in contact with the inorganic layer PVX on the lateral surface of the third dam DAM3. In addition, the second inorganic encapsulation layer 330 may be in contact with the first inorganic encapsulation layer 310 on the lateral surface of the third dam DAM3.

The first inorganic encapsulation layer 310 may cover the edge of the inorganic layer PVX on the upper surface of the substrate 100, and the second inorganic encapsulation layer 330 may cover the edge of the first inorganic encapsulation layer 310 on the upper surface of the substrate 100. This structure may effectively prevent external air from penetrating into the display area. In addition, because the first inorganic encapsulation layer 310, the second inorganic encapsulation layer 330, and the inorganic layer PVX are in contact with each other on the lateral surface of the third dam DAM3, the area of the peripheral area may be remarkably reduced. As the area of the peripheral area PA is reduced, the area of the second corner display area CDA2 may be increased, which may mean the area of the display area of the display apparatus 1 increases.

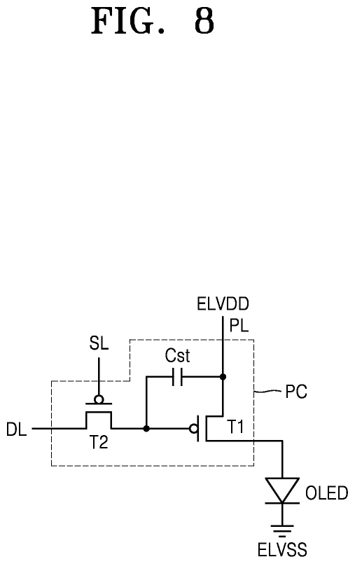

FIG. 8 is an equivalent circuit diagram of the pixel circuit PC applicable to the display panel according to an embodiment.

Referring to FIG. 8, the pixel circuit PC may be connected to the light-emitting element OLED to implement light emission of (sub) pixels. The pixel circuit PC may include a driving thin-film transistor T1, a switching thin-film transistor T2, and a storage capacitor Cst. The switching thin-film transistor T2 is connected to the scan line SL and the data line DL, and configured to transfer a data signal Dm to the driving thin-film transistor T1 according to a scan signal Sn, wherein the data signal Dm is input through the data line DL, and the scan signal Sn is input through the scan line SL.

The storage capacitor Cst may be connected between the switching thin-film transistor T2 and a driving voltage line PL and configured to store a voltage corresponding to a difference between a voltage transferred from the switching thin-film transistor T2 and a driving voltage ELVDD supplied to the driving voltage line PL.

The driving thin-film transistor T1 may be connected between the driving voltage line PL and the light-emitting element OLED and configured to control a driving current according to the voltage stored in the storage capacitor Cst, the driving current flowing from the driving voltage line PL to the light-emitting element OLED. The light-emitting element OLED may be configured to emit light having a preset brightness corresponding to the driving current.

Although it is described with reference to FIG. 8 that the pixel circuit PC includes two thin-film transistors and one storage capacitor, the embodiment is not limited thereto. The pixel circuit PC may include 3 to 9 thin-film transistors, and 1 to 2 capacitors. However, various modifications may be made. The pixel circuit PC is equally applicable to the main pixel circuit PCm and the corner pixel circuit PCc, and a portion of the pixel circuit PC may be changed. However, various modifications may be made to the configuration of the pixel circuit PC. As an example, a capacitance of a storage capacitor included in the main pixel circuit PCm may be different from a capacitance of a storage capacitor included in the corner pixel circuit PCc. Alternatively, the number of thin-film transistors included in the main pixel circuit PCm may be different from the number of thin-film transistors included in the corner pixel circuit PCc. However, various modifications may be made.

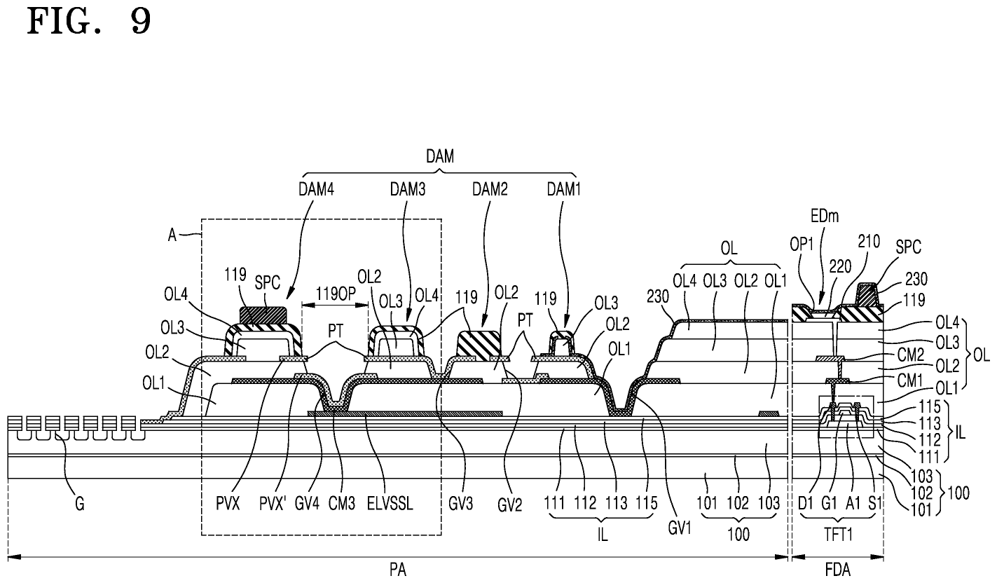

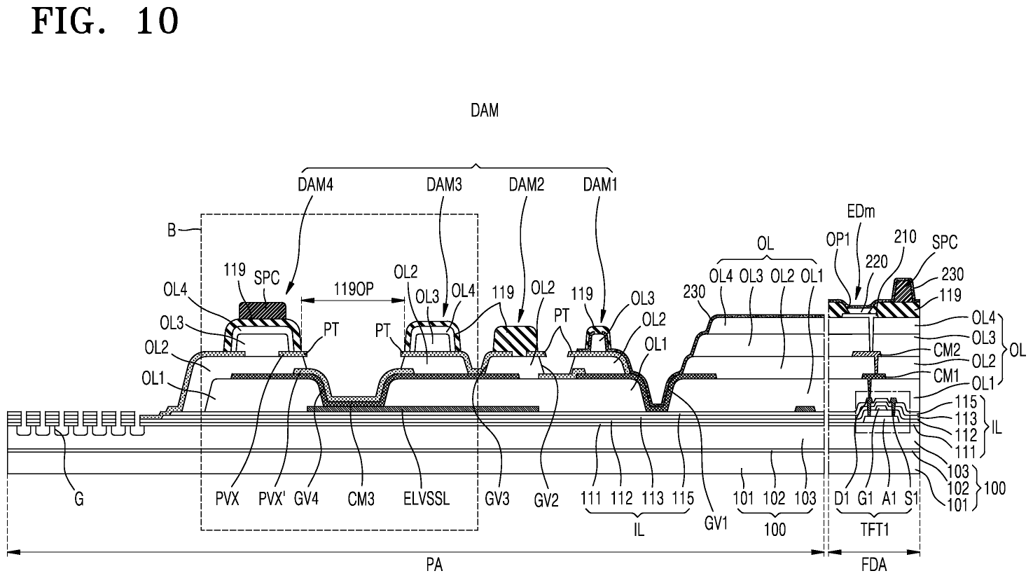

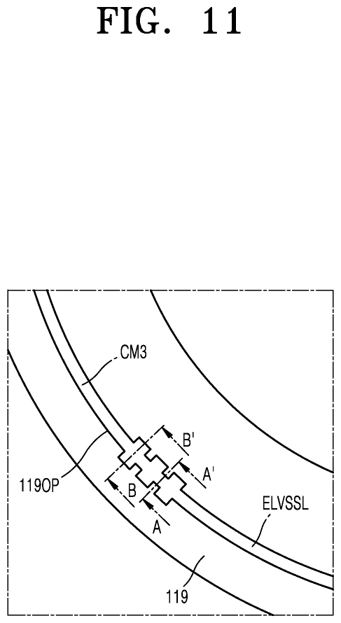

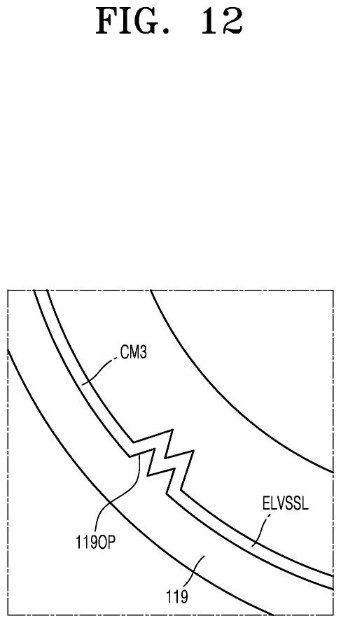

FIGS. 9 and 10 are schematic cross-sectional views of a portion of a display panel according to an embodiment, and FIGS. 11 and 12 are schematic plan views of a portion of a display panel according to an embodiment. Specifically, FIGS. 9 and 10 show a portion of the front display area FDA and the peripheral area PA of the display panel 10. A region A of FIG. 9 may be a region taken along line A-A′ of FIG. 11, and a region B of FIG. 10 may be a region taken along line B-B′ of FIG. 11.

Referring to FIGS. 9 and 10, the main light-emitting element EDm and the main pixel circuit PCm connected to the main light-emitting element EDm may be arranged in the front display area FDA. The main pixel circuit PCm may include a first thin-film transistor TFT1.

The substrate 100 may include an insulating material such as glass, quartz, a polymer resin or the like. The substrate 100 may be a rigid substrate or a flexible substrate that is bendable, foldable, and rollable.

The substrate 100 may include a multi-layer. As an example, the substrate 100 may include a first base layer 101, a first barrier layer 102, a second base layer 103, and a second barrier layer (not shown) that are sequentially stacked.

The first and second base layers 101 and 103 may each include polymer resin. As an example, the first base layer 101 and the second base layer 103 may include a polymer resin such as polyethersulphone (PES), polyarylate (PAR), polyetherimide (PEI), polyethylene naphthalate (PEN), polyethylene terephthalate (PET), polyphenylene sulfide (PPS), polyimide (PI), polycarbonate, cellulose tri acetate (TAC), cellulose acetate propionate (CAP), and the like. The polymer resin may be transparent.

The first base layer 101 and the second base layer 103 each serve as barrier layers preventing the penetration of external foreign materials, and may include a single layer or a multi-layer including an inorganic material such as silicon nitride (SiNₓ) and/or silicon oxide (SiOₓ).

A buffer layer 111 may be disposed on the substrate 100, may reduce or block penetration of foreign materials, moisture, or external air from below the substrate 100, and provide a flat surface on the substrate 100. The buffer layer 111 may include an inorganic material, an organic material, or an organic/inorganic composite material, and include a single layer or a multi-layer including an inorganic material and an organic material, the inorganic material including oxide or nitride. In an embodiment, the buffer layer 111 may include silicon oxide (SiO₂) or silicon nitride (SiNₓ).

The first thin-film transistor TFT1 may be disposed on the buffer layer 111. The first thin-film transistor TFT1 may include a first semiconductor layer A1, a first gate electrode G1, a first source electrode S1, and a first drain electrode D1. The first thin-film transistor TFT1 may be connected to the main light-emitting element EDm to drive the main light-emitting element EDm.

The first semiconductor layer A1 may be disposed on the buffer layer 111 and may include polycrystalline silicon. In another embodiment, the first semiconductor layer A1 may include amorphous silicon. In another embodiment, the first semiconductor layer A1 may include an oxide of at least one of indium (In), gallium (Ga), stannum, zirconium (Zr), vanadium (V), hafnium (Hf), cadmium (Cd), germanium (Ge), chromium (Cr), titanium (Ti), and zinc (Zn). The first semiconductor layer A1 may include a channel region, a source region, and a drain region, the source region and the drain region being doped with impurities.

A first gate insulating layer 112 may be disposed to cover the first semiconductor layer A1. The first gate insulating layer 112 may include an inorganic insulating material such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), or hafnium oxide (HfO₂). The first gate insulating layer 112 may include a single layer or a multi-layer including the inorganic insulating material.

The first gate electrode G1 is disposed on the first gate insulating layer 112 to overlap the first semiconductor layer A1. The first gate electrode G1 may include at least one of molybdenum (Mo), aluminum (Al), copper (Cu), titanium (Ti) and the like and include a single layer or a multi-layer. As an example, the first gate electrode G1 may include a single Mo layer.

A second gate insulating layer 113 may cover the first gate electrode G1. The second gate insulating layer 113 may include an inorganic insulating material such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂). The second gate insulating layer 113 may include a single layer or a multi-layer including the inorganic insulating material. Capacitor electrodes (not shown) may be disposed on the second gate insulating layer 113.

An interlayer insulating layer 115 may be disposed on the second gate insulating layer 113. The interlayer insulating layer 115 may include silicon oxide (SiO₂), silicon nitride (SiNₓ), silicon oxynitride (SiOxNy), aluminum oxide (Al₂O₃), titanium oxide (TiO₂), tantalum oxide (Ta₂O₅), or hafnium oxide (HfO₂). The interlayer insulating layer 115 may include a single layer or a multi-layer including the inorganic insulating material.

The first source electrode S1 and the first drain electrode D1 may be disposed on the interlayer insulating layer 115. The first source electrode S1 and the first drain electrode D1 may each include a conductive material including molybdenum (Mo), aluminum (Al), copper (Cu), and titanium (Ti) and include a single layer or a multi-layer including the above materials. As an example, the source electrode SE and the drain electrode DE may have a multi-layered structure of Ti/Al/Ti.

The organic insulating layer OL may include the first organic insulating layer OL1, the second organic insulating layer OL2, the third organic insulating layer OL3, and the fourth organic insulating layer OL4. The first organic insulating layer OL1 may be disposed on the interlayer insulating layer 115 to cover the first source electrode S1 and the first drain electrode D1. A first connection electrode CM1 may be disposed on the first organic insulating layer OL1, wherein the first connection electrode CM1 is connected to the main pixel circuit PCm. The first connection electrode CM1 may include a conductive material including molybdenum (Mo), aluminum (Al), copper (Cu), and titanium (Ti) and have a single-layered structure or a multi-layered structure including the above materials.

The buffer layer 111, the first gate insulating layer 112, the second gate insulating layer 113, and the interlayer insulating layer 115 may be referred to as inorganic insulating layers IL. The inorganic insulating layer IL may be disposed between the substrate 100 and the main light-emitting element EDm, or between the substrate 100 and the organic insulating layer OL.

The second organic insulating layer OL2 may be disposed on the first organic insulating layer OL1, wherein the second organic insulating layer OL2 covers the first connection electrode CM1. A second connection electrode CM2 may be disposed on the second organic insulating layer OL2. The second connection electrode CM2 may be connected to the first connection electrode CM1 connected to the main pixel circuit PCm.

The second connection electrode CM2 may include a conductive material including molybdenum (Mo), aluminum (Al), copper (Cu), and titanium (Ti) and have a single-layered structure or a multi-layered structure including the above materials. Alternatively, the second connection electrode CM2 may include a transparent conductive material. As an example, the second connection electrode CM2 may include a transparent conductive oxide (TCO). The second connection electrode CM2 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO).

The third organic insulating layer OL3 may be disposed on the second organic insulating layer OL2. The fourth organic insulating layer OL4 may be disposed on the third organic insulating layer OL3. The fourth organic insulating layer OL4 may have a flat upper surface such that a first pixel electrode 210 disposed thereon is formed flat.

The first organic insulating layer OL1, the second organic insulating layer OL2, the third organic insulating layer OL3, and the fourth organic insulating layer OL4 may include a general-purpose polymer such as benzocyclobutene (BCB), polyimide, hexamethyldisiloxane (HMDSO), polymethylmethacrylate (PMMA) or polystyrene, polymer derivatives having a phenol-based group, an acryl-based polymer, an imide-based polymer, an aryl ether-based polymer, an amide-based polymer, a fluorine-based polymer, a p-xylene-based polymer, or a vinyl alcohol-based polymer. The first organic insulating layer OL1, the second organic insulating layer OL2, the third organic insulating layer OL3, and the fourth organic insulating layer OL4 may include the same material or different materials. However, various modifications may be made.

The main light-emitting element EDm may be disposed on the fourth organic insulating layer OL4. The main light-emitting element EDm may include the first pixel electrode 210, a first emission layer 220, and an opposite electrode 230.

The first pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The first pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. As an example, the first pixel electrode 210 may have a structure including layers over/under the reflective layer, the layers including ITO, IZO, ZnO, or In₂O₃. In this case, the first pixel electrode 210 may have a stack structure of ITO/Ag/ITO.

A first bank layer 119 may be disposed on the organic insulating layer OL and may define an emission area of the main light-emitting element EDm. The first bank layer 119 may be disposed on the fourth organic insulating layer OL4. The first bank layer 119 may cover the edge of the first pixel electrode 210 and include a first pixel opening OP1 exposing the central portion of the first pixel electrode 210 in the front display area FDA. The first emission layer 220 may be disposed in the first pixel opening OP1. The size and shape of the emission area of the main light-emitting element EDm may be defined by the first pixel opening OP1.

The first bank layer 119 may prevent arcs and the like from occurring at the edges of the first pixel electrode 210 by increasing a distance between the edges of the first pixel electrode 210 and the opposite electrode 230 over the first pixel electrode 210. The first bank layer 119 may include an organic insulating material such as polyamide, an acryl resin, benzocyclobutene, and hexamethyldisiloxane (HMDSO), and be formed by spin coating and the like. The first bank layer 119 may include a light-absorbing material. As an example, the first bank layer 119 may include black pigment.

A spacer SPC may be disposed on the first bank layer 119. The spacer SPC may be provided to prevent mask chopping during the process of forming the first emission layer 220. The spacer SPC may include an organic insulating material such as polyamide, an acryl resin, benzocyclobutene, and hexamethyldisiloxane (HMDSO), and be formed by spin coating and the like.

The first emission layer 220 may be disposed inside the first pixel opening OP1 of the first bank layer 119. The first emission layer 220 may include a polymer material or a low-molecular weight material and be configured to emit red, green, blue, or white light.

An organic functional layer (not shown) may be disposed over and/or under the first emission layer 220. The organic functional layer of the first emission layer 220 may include a hole injection layer (HIL) and/or a hole transport layer (HTL), an electron transport layer (ETL) and/or an electron injection layer (EIL).

The opposite electrode 230 may be disposed on the first emission layer 220. The opposite electrode 230 may include a conductive material having a low work function. As an example, the opposite electrode 230 may include a (semi) transparent layer including silver (Ag), magnesium (Mg), aluminum (Al), platinum (Pt), palladium (Pd), gold (Au), nickel (Ni), neodymium (Nd), and iridium (Ir), chromium (Cr), lithium (Li), calcium (Ca), or an alloy thereof. Alternatively, the opposite electrode 230 may further include a layer including ITO, IZO, ZnO, or In₂O₃ which is disposed on the (semi) transparent layer.

An upper layer (not shown) including an organic material may be formed on the opposite electrode 230. The upper layer may be a layer for protecting the opposite electrode 230 and simultaneously increasing a light-extracting efficiency. The upper layer may include an organic material having a refractive index higher than that of the opposite electrode 230. In addition, the upper layer may include layers of different refractive indexes that are stacked. As an example, the upper layer may include a high refractive index layer/a low refractive index layer/a high refractive index layer that are stacked. In this case, the refractive index of the high refractive index layer may be 1.7 or more, and the refractive index of the low refractive index layer may be 1.3 or less.

The upper layer may additionally include lithium fluoride (LiF). Alternatively, the upper layer may additionally include an inorganic insulating material such as silicon oxide (SiO₂) and silicon nitride (SiNₓ).

The dam portion DAM including a plurality of dams may be arranged in the peripheral area PA. The dam portion DAM may be a member configured to block an overflow of an organic material forming the organic encapsulation layer 320 when forming the organic encapsulation layer 320 of the thin-film encapsulation layer 300.

The dam portion DAM may include the first dam DAM1, the second dam DAM2, the third dam DAM3, and a fourth dam DAM4. The first dam DAM1, the second dam DAM2, the third dam DAM3, and the fourth dam DAM4 may include the plurality of organic layers, the inorganic layer PVX, and an inorganic protective layer PVX′ that are stacked.

The inorganic layer PVX may include an inorganic insulating material. As an example, the inorganic layer PVX may include a multi-layer or a single layer of an inorganic insulating material such as silicon oxide (SiO₂) and silicon nitride (SiNₓ). In the case where the inorganic layer PVX includes an inorganic insulating material, the inorganic layer PVX may be formed through a separate mask process.

In another embodiment, the inorganic layer PVX may include a metal material. As an example, the inorganic layer PVX may include a metal material including molybdenum (Mo), aluminum (Al), copper (Cu), and titanium (Ti) and have a single-layered structure or a multi-layered structure including the above materials. In the case where the inorganic layer PVX includes a metal material, the inorganic layer PVX may include the same material as a material of the second connection electrode CM2 and be simultaneously formed with the second connection electrode CM2.

The inorganic protective layer PVX′ may be disposed on a peripheral connection electrode CM3. The inorganic protective layer PVX′ may be in contact with the peripheral connection electrode CM3. The inorganic protective layer PVX′ may be formed to cover a portion of the peripheral connection electrode CM3 to prevent the peripheral connection electrode CM3 from being damaged by etchant used when etching the first pixel electrode 210. The inorganic protective layer PVX may include an inorganic material such as silicon nitride (SiNₓ) and/or silicon oxide (SiOₓ).

The first dam DAM1 is a dam arranged closest to the front display area FDA and may include a first layer, a second layer, a third layer, a fourth layer, and a fifth layer that are stacked, wherein the first layer includes the same material as a material of the first organic insulating layer OL1, the second layer includes the same material as a material of the second organic insulating layer OL2, the third layer includes the inorganic layer PVX, the fourth layer includes the same material as a material of the third organic insulating layer OL3, and the fifth layer includes the same material as a material of the first bank layer 119.

The first dam DAM1 may be spaced apart from the organic insulating layer OL extending from the front display area FDA. A first groove GV1 may be formed between the first dam DAM1 and the organic insulating layer OL. That is, the first groove GV1 may be formed between the first dam DAM1 and the organic insulating layer OL, wherein the first groove GV1 exposes the upper surface of the inorganic insulating layer IL. Because the first groove GV1 is formed, external air that may penetrate the front display area FDA may be blocked.

The second dam DAM2 is a dam arranged outside the first dam DAM1 and may include a first layer, a second layer, a third layer, and a fourth layer that are stacked, wherein the first layer includes the same material as a material of the first organic insulating layer OL1, the second layer includes the same material as a material of the second organic insulating layer OL2, the third layer includes the inorganic layer PVX, and the fourth layer includes the same material as a material of the first bank layer 119.

The first dam DAM1 and the second dam DAM2 may share the first layer. A second groove GV2 may be arranged between the second layer of the first dam DAM1 and the second layer of the second dam DAM2. The second layer of the first dam DAM1 may be spaced apart from the second layer of the second dam DAM2. The inorganic layer PVX may include the protrusion tip PT protruding toward the second groove GV2 between the first dam DAM1 and the second dam DAM2. The opposite electrode 230 may be disconnected by the protrusion tip PT. Because the opposite electrode 230 included in the main light-emitting element EDm is disconnected by the protrusion tip PT, a tolerance margin required when depositing the organic layer or the opposite electrode 230 may be reduced. Accordingly, the area of the peripheral area PA may be remarkably reduced.

The third dam DAM3 is a dam arranged outside the second dam DAM2 and may include a first layer, a second layer, a third layer, a fourth layer, a fifth layer, and a sixth layer that are stacked, wherein the first layer includes the same material as a material of the first organic insulating layer OL1, the second layer includes the same material as a material of the second organic insulating layer OL2, the third layer includes the inorganic layer PVX, the fourth layer includes the same material as a material of the third organic insulating layer OL3, the fifth layer includes the same material as a material of the fourth organic insulating layer OL4, and the sixth layer includes the same material as a material of the first bank layer 119. That is, the first bank layer 119 may cover the fourth organic insulating layer OL4 in the peripheral area PA.

The second dam DAM2 and the third dam DAM3 may share the first layer and the third layer. A third groove GV3 may be arranged between the second layer of the second dam DAM2 and the second layer of the third dam DAM3. The second layer of the second dam DAM2 may be spaced apart from the second layer of the third dam DAM3.

The fourth dam DAM4 may be an outermost dam among the plurality of dams of the dam portion DAM. The fourth dam DAM4 may include a first layer, a second layer, a third layer, a fourth layer, a fifth layer, a sixth layer, and a seventh layer that are stacked, wherein the first layer includes the same material as a material of the first organic insulating layer OL1, the second layer includes the same material as a material of the second organic insulating layer OL2, the third layer includes the inorganic layer PVX, the fourth layer includes the same material as a material of the third organic insulating layer OL3, the fifth layer includes the same material as a material of the fourth organic insulating layer OL4, the sixth layer includes the same material as a material of the first bank layer 119, and the seventh layer includes the same material as a material of the spacer SPC. That is, the first bank layer 119 may be in contact with the organic insulating layer OL in the peripheral area PA. The first bank layer 119 may cover the fourth organic insulating layer OL4 in the peripheral area PA. Accordingly, the first bank layer 119 may be in contact with the inorganic layer PVX. A height of the fourth dam DAM4 may be greater than a height of the third dam DAM3. The inorganic layer PVX may cover the upper surface and the lateral surface of the second layer including the same material as a material of the second organic insulating layer OL2.

A fourth groove GV4 may be arranged between the first layer of the third dam DAM3 and the first layer of the fourth dam DAM4. The first layer of the third dam DAM3 may be spaced apart from the first layer of the fourth dam DAM4. The common voltage line ELVSSL may be arranged between the third dam DAM3 and the fourth dam DAM4. That is, the common voltage line ELVSSL may be disposed between the substrate 100 and the organic insulating layer OL in the peripheral area PA. The common voltage line ELVSSL is a wiring configured to transfer a common voltage to the light-emitting elements and may be electrically connected to the opposite electrode 230.

In an embodiment, the common voltage line ELVSSL may be connected to the opposite electrode 230 through the peripheral connection electrode CM3. The peripheral connection electrode CM3 may be disposed on the common voltage line ELVSSL to be in contact with the common voltage line ELVSSL. At least a portion of the peripheral connection electrode CM3 may be disposed between the first organic insulating layer OL1 and the second organic insulating layer OL2. The fourth groove GV4 may serve as a contact hole connecting the common voltage line ELVSSL and the peripheral connection electrode CM3 to each other. The common voltage line ELVSSL may be disposed on the same layer as a layer on which the first source electrode S1 and/or the first drain electrode D1 of the first thin-film transistor TFT1 is disposed. The common voltage line ELVSSL may be disposed on the interlayer insulating layer 115. The common voltage line ELVSSL may be exposed by the fourth groove GV4. The peripheral connection electrode CM3 may include the same material as a material of the first connection electrode CM1 and be disposed on the same layer as a layer on which the first connection electrode CM1 is disposed. The peripheral connection electrode CM3 may be disposed on the first layers of the first dam DAM1 to the fourth dam DAM4 and the first organic insulating layer OL1. In addition, the inorganic layer PVX may be disposed between the second organic insulating layer OL2 and the third organic insulating layer OL3 in the peripheral area PA.

The peripheral connection electrode CM3 may be in direct contact with the common voltage line ELVSSL through the fourth groove GV4. The peripheral connection electrode CM3 may extend from the fourth groove GV4 to the first groove GV1. The peripheral connection electrode CM3 may be in direct contact with the opposite electrode 230 on the lateral surface of the first dam DAM1 or the first groove GV1.

At least a portion of the inorganic layer PVX included in the fourth dam DAM4, which is the outermost dam, may be disposed on a lateral surface close to the substrate 100 among one surface of the fourth dam DAM4 and a lateral surface of the fourth dam DAM4.

When the inorganic layer PVX is not disposed on the lateral surface of the fourth dam DAM4, which is the outermost dam, in order for the thin-film encapsulation layer 300 to block external air, the first inorganic encapsulation layer 310 and the second inorganic encapsulation layer 330 should be in contact with a preset area or more of the upper surface of the inorganic insulating layer IL.

In contrast, according to an embodiment, because the inorganic layer PVX is disposed on the lateral surface of the fourth dam DAM4 to secure a contact region with the inorganic layers on the lateral surface of the fourth dam DAM4, even when a contact region with the inorganic insulating layer IL is reduced on the upper surface of the substrate 100, external air may be sufficiently blocked. Accordingly, the area of the peripheral area PA may be reduced. As the area of the peripheral area PA is reduced, the area of the front display area FDA may be increased.

The first bank layer 119 may include a first alignment opening 119OP in the peripheral area PA. The common voltage line ELVSSL may overlap the first alignment opening 119OP. That is, the common voltage line ELVSSL may be exposed from the first bank layer 119 through the first alignment opening 119OP. Accordingly, the peripheral connection electrode CM3 disposed on the common voltage line ELVSSL may overlap the first alignment opening 119OP. The inorganic protective layer PVX disposed on the peripheral connection electrode CM3 may overlap the first alignment opening 119OP. The first bank layer 119 disposed on the front display area FDA and the first bank layer 119 disposed on the peripheral area PA may be simultaneously formed through the same process.

A plurality of grooves G may be disposed between the edge of the substrate 100 and the dam portion DAM, wherein the plurality of grooves G are formed by removing a portion of the inorganic insulating layer IL and the substrate 100. As an example, the plurality of grooves G may include holes formed through the inorganic insulating layer IL and recesses formed in the second base layer 103 of the substrate 100. The inorganic insulating layer IL may include the protrusion tip PT protruding into the groove G. The plurality of grooves G may be designed to prevent propagation of cracks that may occur when cutting the edge of the substrate 100.

Referring to FIGS. 9 and 10, the width of the first alignment opening 119OP may be different depending on the cross-section of the display panel 10 at different positions. As an example, a distance between the third dam DAM3 and the fourth dam DAM4 shown in FIG. 10 may be greater than a distance between the third dam DAM3 and the fourth dam DAM4 shown in FIG. 9. Accordingly, the width of the first alignment opening 119OP shown in FIG. 10 may be greater than the width of the first alignment opening 119OP shown in FIG. 9.

In this structure, referring to FIG. 11, the first alignment opening 119OP may form an alignment pattern in a plan view. The first bank layer 119 including a light-absorbing material may absorb light entering from the outside, and the common voltage line ELVSSL and the peripheral connection electrode CM3 exposed through the first alignment opening 119OP may reflect light.

As an example, as shown in FIG. 11, the first alignment opening 119OP may include a plurality of cross shapes. That is, the alignment pattern may include a main portion extending along a first direction and cross portions crossing substantially perpendicular to the main portion, and be formed by adjusting a width of the first alignment opening 119OP in the cross portions. However, this is an example and the alignment pattern is not limited thereto. As an example, as shown in FIG. 12, the alignment pattern may include a zigzag shape. In this structure, the width of the first alignment opening 119OP may be constant. The alignment pattern may serve as an identification key for recognizing alignment of the substrate 100.

In this structure, because the alignment pattern is not separately provided outside the common voltage line ELVSSL but is disposed on the common voltage line ELVSSL and the peripheral connection electrode CM3, the area of the peripheral area PA may be reduced. In addition, because the alignment pattern are not formed using a patterning method but are formed according to the shape of the first alignment opening 119OP of the first bank layer 119, electrical characteristics such as a resistance of the wirings such as the common voltage line ELVSSL and the peripheral connection electrode CM3 are not influenced by a formation of the alignment pattern.

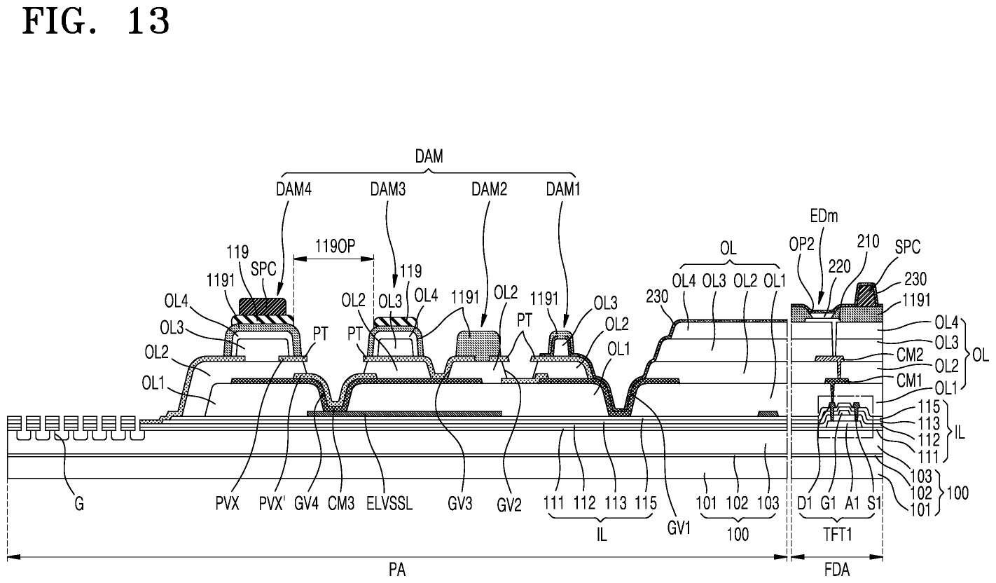

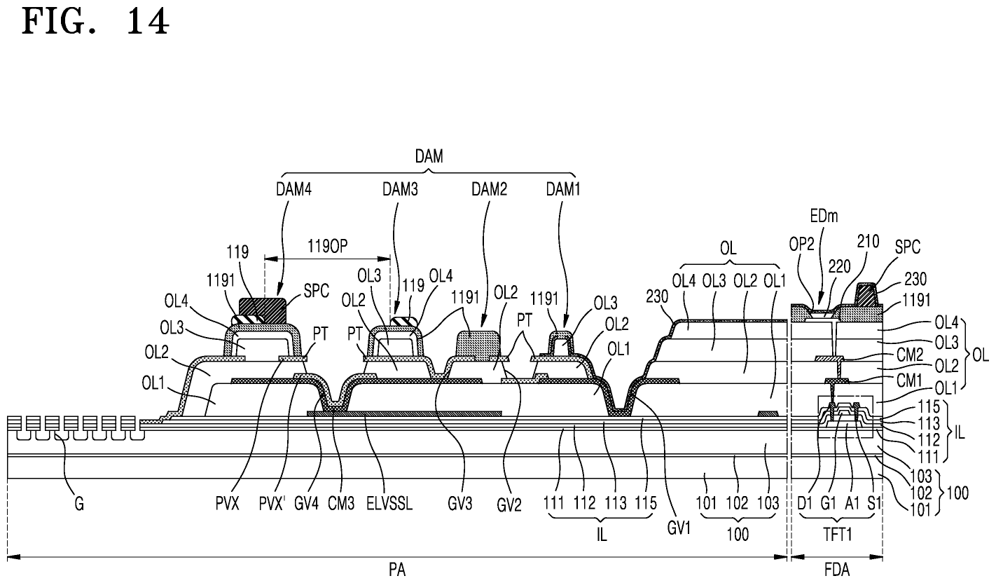

FIGS. 13 and 14 are schematic cross-sectional views of a portion of the display panel 10 according to an embodiment. Specifically, FIGS. 13 and 14 show a portion of the front display area FDA and the peripheral area PA of the display panel 10.

In FIGS. 13 and 14, the same reference numerals as those of FIGS. 9 and 10 denote the same members, and thus, repeated descriptions thereof are omitted.

Referring to FIGS. 13 and 14, a second bank layer 1191 may be further included compared to the embodiment described with reference to FIGS. 9 and 10.

The second bank layer 1191 may be disposed on the organic insulating layer OL and may define an emission area of the main light-emitting element EDm. The second bank layer 1191 may be disposed on the fourth organic insulating layer OL4. The second bank layer 1191 may include a second pixel opening OP2 in the front display area FDA. The second bank layer 1191 may cover the edge of the first pixel electrode 210 and include a second pixel opening OP2 exposing the central portion of the first pixel electrode 210 in the front display area FDA. The first emission layer 220 of the main light-emitting element EDm may be disposed in the second pixel opening OP2. The size and shape of the emission area of the main light-emitting element EDm may be defined by the second pixel opening OP2. The second bank layer 1191 may include an organic insulating material such as polyamide, an acryl resin, benzocyclobutene, and hexamethyldisiloxane (HMDSO), and be formed by spin coating and the like.

The first dam DAM1 may include a first layer, a second layer, a third layer, a fourth layer, and a fifth layer that are stacked, wherein the first layer includes the same material as a material of the first organic insulating layer OL1, the second layer includes the same material as a material of the second organic insulating layer OL2, the third layer includes an inorganic layer, the fourth layer may include the same material as a material of the third organic insulating layer OL3, and the fifth layer may include the same material as a material of the second bank layer 1191.

The second dam DAM2 may include a first layer, a second layer, a third layer, and a fourth layer that are stacked, wherein the first layer includes the same material as a material of the first organic insulating layer OL1, the second layer includes the same material as a material of the second organic insulating layer OL2, the third layer includes an inorganic layer, and the fourth layer may include the same material as a material of the second bank layer 1191.

The third dam DAM3 may include a first layer, a second layer, a third layer, a fourth layer, a fifth layer, a sixth layer, and a seventh layer that are stacked, wherein the first layer includes the same material as a material of the first organic insulating layer OL1, the second layer includes the same material as a material of the second organic insulating layer OL2, the third layer includes the inorganic layer, the fourth layer includes the same material as a material of the third organic insulating layer OL3, the fifth layer includes the same material as a material of the fourth organic insulating layer OL4, the sixth layer includes the same material as a material of the second bank layer 1191, and the seventh layer includes the same material as a material of the first bank layer 119.

The fourth dam DAM4 may include a first layer, a second layer, a third layer, a fourth layer, a fifth layer, a sixth layer, a seventh layer, and an eighth layer that are stacked, wherein the first layer includes the same material as a material of the first organic insulating layer OL1, the second layer includes the same material as a material of the second organic insulating layer OL2, the third layer includes the inorganic layer, the fourth layer includes the same material as a material of the third organic insulating layer OL3, the fifth layer includes the same material as a material of the fourth organic insulating layer OL4, the sixth layer includes the same material as a material of the second bank layer 1191, the seventh layer includes the same material as a material of the first bank layer 119, and the eighth layer includes the same material as a material of the spacer SPC.

The second bank layer 1191 may be disposed between the organic insulating layer OL and the first bank layer 119 in the peripheral area PA. The first bank layer 119 may be in contact with the upper surface of the second bank layer 1191. The first bank layer 119 may be spaced apart from the organic insulating layer OL and the inorganic layer.

Referring to FIGS. 13 and 14, the width of the first alignment opening 119OP may be different depending on the cross-section of the display panel 10 at different positions. A distance between the first bank layer 119 disposed in the third dam DAM3 and the first bank layer 119 disposed in the fourth dam DAM4 shown in FIG. 13 may be less than a distance between the first bank layer 119 disposed in the third dam DAM3 and the first bank layer 119 disposed in the fourth dam DAM4 shown in FIG. 14. Accordingly, the width of the first alignment opening 119OP shown in FIG. 13 may be less than the width of the first alignment opening 119OP shown in FIG. 14. Accordingly, the alignment pattern may be formed in a way of adjusting the width of the first alignment opening 119OP.

As described above, the display panel and the display apparatus according to an embodiment include the corner display area, and thus, the area in which images are displayed may be extended.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a substrate including a display area and a peripheral area around the display area;
an organic insulating layer disposed on the substrate;
a light-emitting element disposed on the substrate in the display area;
a first bank layer including a light absorbing-material, disposed on the organic insulating layer, and including a first alignment opening in the peripheral area; and
a common voltage line disposed between the substrate and the organic insulating layer in the peripheral area, and overlapping the first alignment opening in a plan view,
wherein the first alignment opening forms an alignment pattern.

2. The display panel of claim 1, wherein the first bank layer includes a first pixel opening in the display area and the light-emitting element is disposed in the first pixel opening.

3. The display panel of claim 1, wherein the first bank layer is in contact with the organic insulating layer in the peripheral area.

4. The display panel of claim 1, further comprising a peripheral connection electrode disposed on the common voltage line to be in contact with the common voltage line,
wherein the peripheral connection electrode overlaps the first alignment opening.

5. The display panel of claim 4, wherein the organic insulating layer includes:
a first organic insulating layer; and
a second organic insulating layer disposed on the first organic insulating layer, and
wherein at least a portion of the peripheral connection electrode is disposed between the first organic insulating layer and the second organic insulating layer.

6. The display panel of claim 4, further comprising an inorganic protective layer disposed on the peripheral connection electrode to be in contact with the peripheral connection electrode,
wherein the inorganic protective layer overlaps the first alignment opening.

7. The display panel of claim 1, wherein the organic insulating layer includes:
a third organic insulating layer disposed on a second organic insulating layer; and
a fourth organic insulating layer disposed on the third organic insulating layer, and
wherein the first bank layer covers the fourth organic insulating layer in the peripheral area.

8. The display panel of claim 7, further comprising an inorganic layer disposed between the second organic insulating layer and the third organic insulating layer in the peripheral area.

9. The display panel of claim 8, wherein the first bank layer is in contact with the inorganic layer.

10. The display panel of claim 1, further comprising a second bank layer disposed on the organic insulating layer and including a second pixel opening in the display area,
wherein the light-emitting element is disposed in the second pixel opening and the second bank layer is disposed between the organic insulating layer and the first bank layer in the peripheral area.

11. A display apparatus comprising:
a cover window including a plane portion and a curved portion bent in a corner of the plane portion; and
a display panel disposed on one surface of the cover window,
wherein the display panel includes:
a substrate including a display area and a peripheral area surrounding the display area, wherein the display area overlaps the plane portion;
an organic insulating layer disposed on the substrate;
a light-emitting element disposed on the substrate in the display area;
a first bank layer including a light-absorbing material, disposed on the organic insulating layer, and including a first alignment opening in the peripheral area; and
a common voltage line disposed between the substrate and the organic insulating layer in the peripheral area, and overlapping the first alignment opening in a plan view,
wherein the first alignment opening forms an alignment pattern.

12. The display apparatus of claim 11, wherein the first bank layer includes a first pixel opening in the display area and the light-emitting element is disposed in the first pixel opening.

13. The display apparatus of claim 12, wherein the first bank layer is in contact with the organic insulating layer in the peripheral area.

14. The display apparatus of claim 11, further comprising a peripheral connection electrode disposed on the common voltage line to be in contact with the common voltage line,
wherein the peripheral connection electrode overlaps the first alignment opening.

15. The display apparatus of claim 14, wherein the organic insulating layer includes:
a first organic insulating layer; and
a second organic insulating layer disposed on the first organic insulating layer, and
wherein at least a portion of the peripheral connection electrode is disposed between the first organic insulating layer and the second organic insulating layer.

16. The display apparatus of claim 14, further comprising an inorganic protective layer disposed on the peripheral connection electrode to be in contact with the peripheral connection electrode, wherein the inorganic protective layer overlaps the first alignment opening.

17. The display apparatus of claim 11, wherein the organic insulating layer includes:
a third organic insulating layer disposed on a second organic insulating layer; and
a fourth organic insulating layer disposed on the third organic insulating layer, and
wherein the first bank layer covers the fourth organic insulating layer in the peripheral area.

18. The display apparatus of claim 17, further comprising an inorganic layer disposed between the second organic insulating layer and the third organic insulating layer in the peripheral area.

19. The display apparatus of claim 18, wherein the first bank layer is in contact with the inorganic layer.

20. The display apparatus of claim 11, further comprising a second bank layer disposed on the organic insulating layer in the display area and including a second pixel opening,
wherein the light-emitting element is disposed in the second pixel opening and the second bank layer is disposed between the organic insulating layer and the first bank layer in the peripheral area.
